(19) United States
(12) Patent Application Publication
(10) Pub. No.: US 2026/0338720 A1
(43) Pub. Date: Oct. 29, 2026

(54) FAST PHOTOEMISSION ELECTRON MICROSCOPY FOR BIOLOGICAL AND OTHER APPLICATIONS

(71) Applicants: The University of Chicago, Chicago, IL (US); The Board of Trustees of the University of Illinois, Urbana, IL (US)

(72) Inventors: Sarah B. King, Chicago, IL (US); Narayanan Kasthuri, Chicago, IL (US); Peter B. Littlewood, Chicago, IL (US); Kevin Michael Boergens, Chicago, IL (US); Ruiyu Li, Chicago, IL (US); Gregg Anthony Wildenberg, Chicago, IL (US)

(21) Appl. No.: 19/485,556

(22) PCT Filed: May 30, 2024
(86) PCT No.: PCT/US2024/031542

§ 371 Date: Nov. 18, 2025

Related U.S. Application Data
(60) Provisional application No. 63/470,042, filed on May 31, 2023.

(51) Int. Cl. G01N 23/227

(52) U.S. Cl. CPC G01N 23/227; G01N 2223/612

(57) ABSTRACT

An imaging system comprising a light source configured to radiate a biological sample, wherein the light source is optimized for rapid imaging of the biological sample using a photoelectric effect. The system also includes a sample holder configured to secure the biological sample during imaging. The system also includes a stage assembly to which the sample holder is mounted, where stage assembly moves the biological sample during imaging. The system further includes a detector configured to receive electrons emitted from the biological sample in response to radiation from the light source.

### CROSS-REFERENCE TO RELATED APPLICATION

The present application claims the priority benefit of U.S. Provisional Patent App. No. 63/470,042 filed on May 31, 2023, the entire disclosure of which is incorporated by reference herein.

### BACKGROUND

An electron microscope is a type of microscope that uses a beam of electrons (which has wavelike characteristics with a short wavelength) to create a magnified image of a sample. This is in contrast to a traditional optical microscope, which utilizes visible light to create a magnified image of an object. There are several different kinds of electron microscopes. For example, a transmission electron microscope (TEM) is generally used to view a thin sample by passing electrons through the sample to generate a projection image. A scanning electron microscope is generally used to view a sample by scanning an electron beam over the surface of sample and generating an image based on local variations in the emission of electrons of varying energy from the sample due to the interaction of the initial beam of elections with the sample. Another type of electron microscope is a photoemission electron microscope (PEEM). A PEEM uses photons to cause emission of electrons from a sample and utilizes local variations in the electron emission to generate image contrast.

### SUMMARY

An illustrative imaging system includes a light source configured to radiate a biological sample, where the light source is optimized for rapid imaging of the biological sample using a photoelectric effect. The system includes a sample holder configured to secure the biological sample during imaging. The system also includes a stage assembly to which the sample holder is mounted, where stage assembly moves the biological sample during imaging. The system further includes a detector configured to receive electrons emitted from the biological sample in response to radiation from the light source.

In one embodiment, the light source comprises a continuous-wave (CW) laser. In another embodiment, the light source comprises a frequency-quadrupled neodymium-doped yttrium aluminum garnet (Nd:YAG) laser with a wavelength in a range between 244 nanometers and 254 nanometers. In another embodiment, the stage assembly comprises a piezo driven flexure stage optimized for rapid imaging. In another embodiment, the detector comprises a time, delay, and integration sensor optimized for rapid imaging. In one embodiment, the biological sample is thin cut and the sample holder includes a wafer sized to hold the biological sample. In some embodiments, a reflective coating is placed on the sample holder to mitigate negative effects of heat deposition during imaging.

In one embodiment, the system includes one or more mirrors that direct light from the light source onto the biological sample. The system can also include an active alignment mechanism configured to align the light source with the biological sample. In other embodiments, the system includes a fiber cable connected to the light source, where the fiber cable is also connected to a vacuum chamber where imaging takes place. The system can also include an objective lens configured to focus radiation from the light source onto a region of interest (ROI) of the biological sample.

In an illustrative embodiment, the stage assembly includes a plurality of stages combined in aggregate to provide both speed and a lack of vibration over a range of travel that exceeds a size of the biological sample. In one embodiment, a first stage in the plurality of stages is a cross roller bearing stage and a second stage in the plurality of stages is a piezo driven flexure stage or a magnetic bearing stage. The system can also include one or more sensors to monitor a Z stage of the stage assembly that moves in a Z-direction, where the one or more sensors identify any movement errors in the Z-direction. In another embodiment, a vacuum aperture is positioned between the biological sample and the stage assembly such that the stages of the stage assembly and the biological sample can be separately pumped.

In another embodiment, the detector is configured for continuous imaging while the sample is moving. The system can also include an electric or electromagnetic deflector in a path of the electrons emitted from the biological sample to deflect the electrons using a sawtooth deflection amplitude.

In another embodiment, the sample holder includes a wafer submerged in water, where the biological sample is received on the water, and where the water is removed via draining or evaporation such that the biological sample is positioned on the wafer. In another embodiment, the biological sample is fused with a block of magnetic material such that a position of the biological sample received on the water can be manipulated by a magnet.

In another embodiment, a staining agent is introduced into the biological sample to highlight one or more regions of the biological sample, where the staining agent has a modified electron yield during photoemission conditions. In one embodiment, the biological sample is stained with Osmium tetroxide and embedded in epoxy such that the biological sample stained with Osmium tetroxide has an increased electron yield compared to the epoxy. In another embodiment, the slices are collected on a surface coated in gold. In another embodiment, the sample holder is treated with laser radiation to prevent outgassing from occurring during imaging. In one embodiment, the sample holder is treated with ionic radiation to remove a portion of the sample one or more times during imaging. In another embodiment, the sample holder is made from copper with high thermal conductivity to aid in heat mitigation during imaging. In one embodiment, a treatment is applied to the sample holder to minimize light absorption, where the treatment makes the sample holder transparent to light having a wavelength used to elicit the electrons. In another embodiment, a surface of the sample holder is modified into a Bragg mirror to make the sample holder reflective and thereby minimize light absorption.

Other principal features and advantages of the invention will become apparent to those skilled in the art upon review of the following drawings, the detailed description, and the appended claims.

### BRIEF DESCRIPTION OF THE DRAWINGS

Illustrative embodiments of the invention will hereafter be described with reference to the accompanying drawings, wherein like numerals denote like elements.

FIG. 1 depicts an overview of a photoemission electron microscope imaging a biological sample in accordance with an illustrative embodiment.

FIG. 2 shows a stage assembly arrangement that allows for fast and/or continuous movement of the sample during imaging in accordance with an illustrative embodiment.

FIG. 3 illustrates imaging strategies to image successfully during stage movement in accordance with an illustrative embodiment.

FIG. 4 depicts a sample holder that is optimized to image a large number of thin samples (such as thin biological tissue slices) at high speed in accordance with an illustrative embodiment.

FIG. 5 shows a computer system that is programmed or otherwise configured to implement a method for acquiring PEEM images of biomedical samples with accelerated throughput in accordance with an illustrative embodiment.

FIG. 6 is a representative image of an 80-nm thick sample section illuminated by a mercury lamp in accordance with an illustrative embodiment.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### DETAILED DESCRIPTION

Transmission electron microscopy and scanning electron microscopy are tools often used for biomaterial imaging and/or high throughput image acquisition. Photoemission electron microscopy (PEEM) is a promising alternative for these types of imaging scenarios, with the ability to improve acquisition speed, ease of sample preparation, and the amount of information extractable per image. Photoemission electron microscopy has been used successfully in a variety of material science applications. However, traditional PEEM systems have only very sporadically been used for imaging of biological/medical samples due to the fact that neither the speed of the microscope nor its contrast mechanism have been optimized for biomedical imaging.

Described herein is a PEEM that is optimized for biomedical imaging, referred to herein as ‘BioPEEM’ or the proposed system. In an illustrative embodiment, the proposed system can include an imaging column, a stage mechanism, a light source, a detector, customized automation software, an analysis pipeline, and a variety of sample preparation steps that are specifically tailored for improved performance in the imaging of biomedical samples. In alternative implementations, the proposed system can include fewer, additional, and/or different elements.

Another aspect of the present disclosure provides methods to extract more than one greyscale image per sample. For example, chemical or material staining agents with different work functions, ionization potentials, electron densities, or oxidation states can be used to extract multiple greyscale images per sample. Alternatively, the sample material can be probed with photons of varying energies in order to achieve differential contrast or sample information from different depths. Additionally, described herein is the use of an energy filter that allows for the acquisition of additional channels in the composite image which is assembled.

Another aspect of the present disclosure is directed to a non-transitory computer readable medium comprising machine executable code that, upon execution by one or more computer processors, implements any of the methods described herein. Another aspect of the present disclosure is directed to a system that includes one or more computer processors and computer memory coupled thereto. The computer memory includes machine executable code that, upon execution by the one or more computer processors, implements any of the methods described herein.

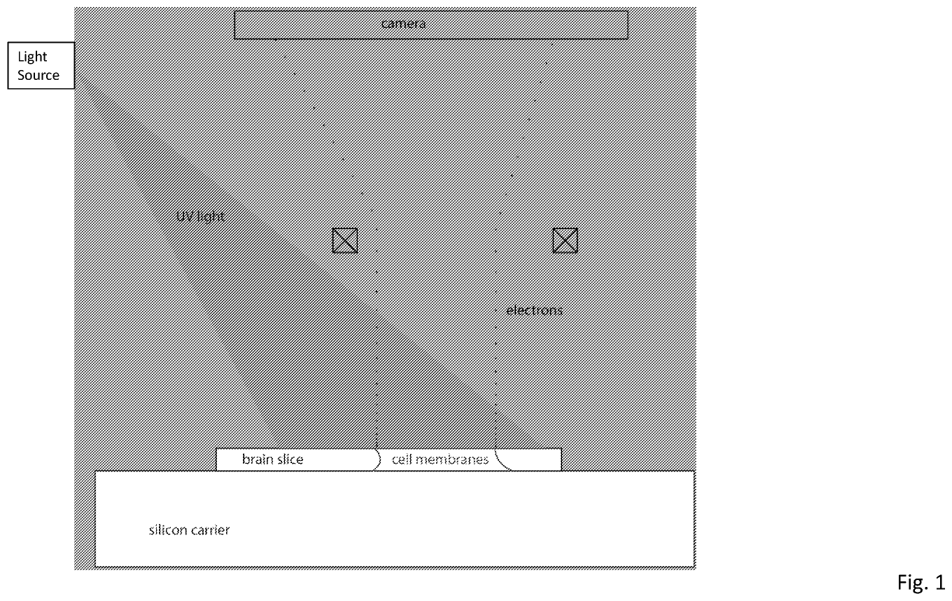

As discussed, the present disclosure is directed to systems and methods for an improved photoemission electron microscope (PEEM) that is optimized for biomedical imaging. The proposed microscope operates by irradiating a sample with photons and having those photons produce photoelectrons, which are emitted from the sample. FIG. 1 depicts an overview of a photoemission electron microscope imaging a biological sample in accordance with an illustrative embodiment. In the embodiment shown, the sample being imaged is a brain slice with cell membranes positioned on a silicon carrier. In alternative scenarios, any other type of biological material may be sampled.

In an illustrative embodiment, a light source is used to emit a beam of photons to excite the sample being imaged. In one embodiment, the photons used for excitation can have wavelengths of 157 nanometers (nm). Alternatively, the wavelengths can be less than 157 nm, more than 157 nm, 300 nm, 400 nm, 500 nm, 600 nm, 700 nm, etc. The light source can be a laser or a mercury lamp in one embodiment. Alternatively, a different type of light source may be used. In the embodiment of FIG. 1, the light source emits high intensity ultraviolet (UV) light to irradiate the sample. In alternative implementations, a different type of high intensity excitation light may be used. Due to this high intensity of the light source, image acquisition time can be very short, such as less than 10 minutes (min), 1 min, 30 seconds(s), 10 s, 5 s, 1 s, 100 milliseconds (ms), 10 ms, 5 ms, 1 ms, etc. To allow for such fast imaging, the microscope can be operated in such a way that it performs imaging while the sample is moving, leading to a scenario with little or no lost time due to stage movements.

In response to being excited by the photons from the light source, electrons are emitted from the sample. The electrons leave the sample due to their own kinetic energy and are then accelerated towards an objective lens of a camera or detector. In one embodiment, the acceleration voltage of the emitted electrons can be 10 kiloVolts (kV). Alternatively, the acceleration voltage can be less than 10 kV, more than 10 kV, 15 kV, 20 kV, 25 kV, etc. The image constituted by the emitted electrons is magnified by one or more electrostatic or electromagnetic lenses, and projected onto a detector. The detector can be a direct electron detector in one embodiment. Alternatively, the detector can utilize microchannel plates and/or a scintillator.

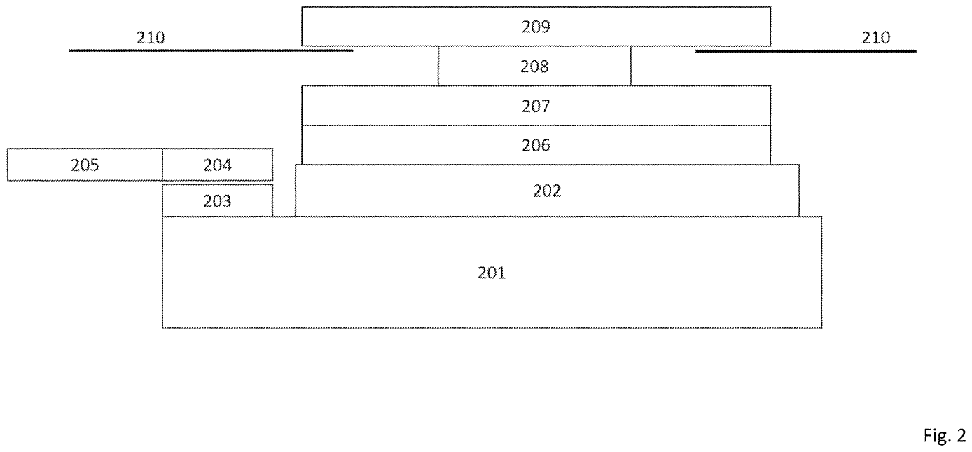

FIG. 2 shows a stage assembly arrangement that allows for fast and/or continuous movement of the sample during imaging in accordance with an illustrative embodiment. In some embodiments the order of the stages in the stage assembly may be shuffled. The stage assembly includes an XY stage 201 that moves in both the X direction and the Y direction with a sufficient motion range to cover whole samples. Such a stage can have a range of 1 inch in each of the X and Y directions in one embodiment. Alternatively, the motion range in the XY directions can be less than 1 inch, more than 1 inch, 2 inches, 3 inches, 4 inches, 5 inches, 6 inches, etc. In some embodiments, the XY stage 201 can be a direct drive crossed roller-bearing stage.

The stage assembly also includes a high precision short distance Z stage 202, used for Z error compensation of the XY stage 201 and/or for focusing the microscope. The Z stage 202 can have a motion range of travel in the Z direction of 100 micrometer (μm) in one embodiment. Alternatively, the motion range of the Z stage 202 can be more than 100 μm, less than 100 μm, less than 10 μm, less than 1 μm, etc. The stage assembly also includes a first measurement device 203 and a second measurement device 204, which together form a contactless Z distance measurement device. The contactless Z distance measurement device is used to measure the Z error of the XY stage 201, and to issue a movement command to the Z stage 202 to correct for any measured error. Specifically, as the stage moves in the X and Y directions, it wobbles up and down thereby changing the Z position of the sample in erroneous ways. This variation in the Z direction is detected with the contactless Z measurement device, which can be in the form of a capacitive or interferometer sensor in one embodiment. The contactless Z distance measurement device 203/204 includes a holder 205 to which the measurement device is mounted. In one embodiment, the holder 205 is made out of a material with a low thermal expansion coefficient, such as Invar.

The stage assembly of FIG. 2 also includes an X stage 206 that moves in the X direction and a Y stage 207 that moves in the Y direction. The X stage 206 and the Y stage 207 are optimized for movement without the creation of high frequency movement noise, as is present in many other types of stages. For example, the XY state 201 can have a large range of motion that includes undesired movement in the form vibrations, deviations, etc.

Conversely, the X stage 206 and the Y stage 207 can have small range of movements that are very smooth and that avoid the vibrations, etc. of the XY stage 201. The root mean square (RMS) movement error of these stages can be below 30 nm, 20 nm, 10 nm, 5 nm, 2 nm, etc. in a frequency range above 500 Hertz (Hz). In some embodiments, the X stage 206 and the Y stage 207 can be combined into a single XY stage. In an illustrative embodiment, the X stage 206 and the Y stage 207 may be piezo driven flexure stages or magnetic bearing stages. In one embodiment, the X stage 206 and the Y stage 207 can each have a motion range of 100 μm. Alternatively, the motion ranges of the stages can be less than 100 μm, more than 100 μm, 500 μm, 1 mm, 2 mm, 4 mm, etc.

The stage assembly further includes a sample holder 208. The sample holder 208 can hold the sample mechanically, magnetically, or by using an adhesive. In some embodiments, the sample holder 208 may be part of a wafer loading and handling system.

Also depicted in FIG. 2 is a sample 209 positioned on the sample holder 208. In some embodiments the sample 209 may be a wafer that is optimized for weight to allow for fast stage movement. In one embodiment, the sample 209 can be a wafer whose backside has been structured to reduce weight while maintaining stiffness, a wafer made from a material that has a favorable stiffness to weight ratio such as titanium, or a sandwich structure of a thin wafer and a holder structure made from a different material and/or being structured to support the thin wafer. In some embodiments the sample 209 may be optimized for laser heat dissipation. In another embodiment, a vacuum aperture may be installed to separate the sample chamber into two separate volumes. The vacuum aperture can include a vacuum gate valve that may be placed between two vacuum chambers for embodiments in which two chambers are needed to perform the analysis This allows the stage area to be at a lower vacuum, such as less than 10-11 torr, 10-10 torr, 10-9 torr, 10-8 torr, 10-7 torr, 10-6 torr, 10-5 torr, 10-4 torr, etc. In an illustrative embodiment, the stage does not come to rest while the image acquisition is occurring. In some embodiments, it is not possible to image with fast enough pulses (stroboscopelike) due to space-charge effects of the elicited electrons.

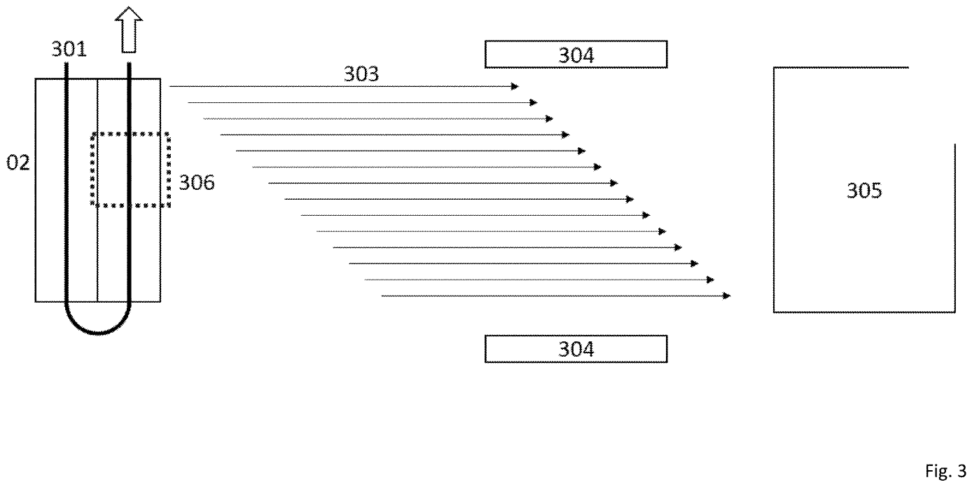

FIG. 3 illustrates imaging strategies to image successfully during stage movement in accordance with an illustrative embodiment. FIG. 3 shows an example trajectory 301 of a stroke that a sample can take during imaging. Depending on the desired imaging being performed, there may be 1 or more, 5, 10, 50, 100, 500, or more of such strokes represented by the trajectory 301. The strokes may overlap by a value of less than 1%, more than 1%, more than 5%, or more than 10% of the stroke width 302. While the sample is moving, an illumination region 306 does not move, meaning that in the reference system of the microscope that emitted electrons 303 always originate from the same region. The electrons 303 are flying through the column and for a given source point their X and Z positions are correlated as dictated by the movement of the stage. Therefore, the detector assembly has to ensure that there is a correct attribution of electrons to source point.

Ensuring that there is a correct attribution of received electrons to their source point may be achieved by reading out a camera 305 at very high frame rate and algorithmically correcting for the movement. In another embodiment, the attribution of electrons may be achieved by using a Time, Delay, and Integration (TDI) detector, which is a type of charge coupled device (CCD) detector purposely built for this scenario. In other embodiments, the electron attribution may be achieved by deflecting the electrons using electrostatic or electromagnetic beam deflection devices 304, thereby compensating for the sample movement. In another embodiment the detector may be moved physically to counteract continuous movement of the sample.

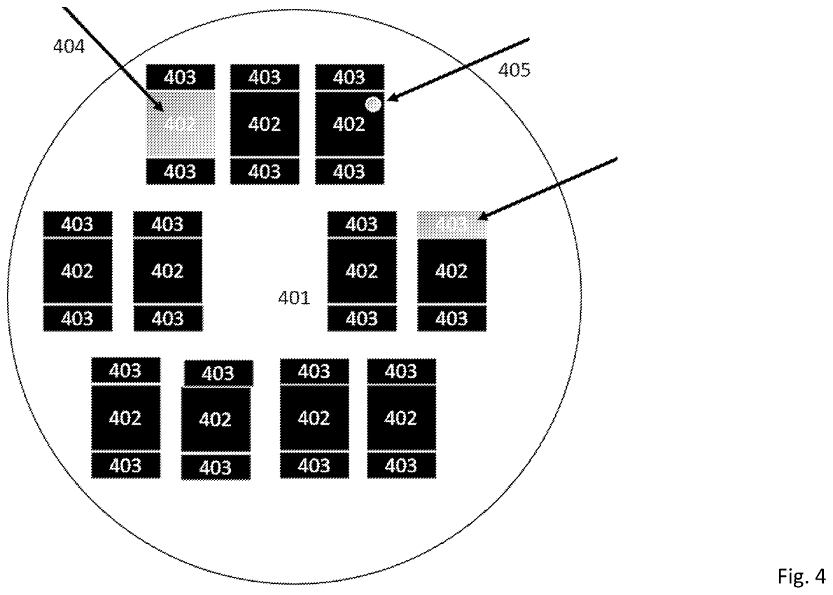

The proposed microscope can be used to image a wide variety of samples, both biomedical in origin and otherwise. FIG. 4 depicts a sample holder 401 that is optimized to image a large number of thin samples (such as thin biological tissue slices) at high speed in accordance with an illustrative embodiment. In some embodiments, the sample holder 401 may be round and/or a wafer. The material of the wafer can be optimized for thermal conductance and/or transparency. In some embodiments the wafer may be made from silver, copper, fused silica, or calcium fluoride. In some embodiments the wafer may be coated with a material to increase reflectivity, such as modified aluminum or a bragg mirror structure. The wafer may be also coated in such a way as to improve the interaction between the samples and the sample holder 401, such as gold coating or silane treatment.

In an illustrative embodiment, the sample material 402 can be biological in nature, and can be treated with Osmium tetroxide, lead aspartate, uranyl acetate or similar substances as a staining agent. In some embodiments the sample material 402 may be epoxy embedded and/or the sample material 402 may be optimized to be less absorptive to the wavelength of the incoming photons and/or optimized to minimize sample damage due to UV radiation. In an illustrative embodiment, the sample material 402 may be fused to magnetic material 403. The wafer may be loaded by submerging it in a liquid, having the samples float on top of the liquid, and then draining or evaporating the liquid. In these embodiments the magnetic material may be used to move, manipulate, and/or orient the sample material 402. In some embodiments the sample material 402 may be treated with ionic radiation 404 to remove material. The ionic radiation treatment can happen before the imaging and/or during imaging runs. For example, the ionic radiation treatment can occur 1, 2, 3, 4, 5, 6, 7, 8, 9, 10, 100, or more times interleaved between imaging runs. In another embodiment, the control system may use prior imaging data as the basis to predict ion milling yields and adjust dwell time accordingly to ensure a homogeneous milling effect.

In an illustrative embodiment, the ionic radiation treatment can be used to achieve a three-dimensional (3D) imaging effect of the sample material 402. In some embodiments the sample may be treated with laser radiation before imaging 405 occurs. The laser radiation can be used to outgas the sample and/or to remove improperly attached material so that it will not distort the electric field or burn off in the imaging vacuum. In some embodiments the magnetic material 403 may be treated with a heat inducing radiation (such as laser light) to heat it above its Curie temperature and remove its magnetism such that the magnetism does not negatively influence the imaging.

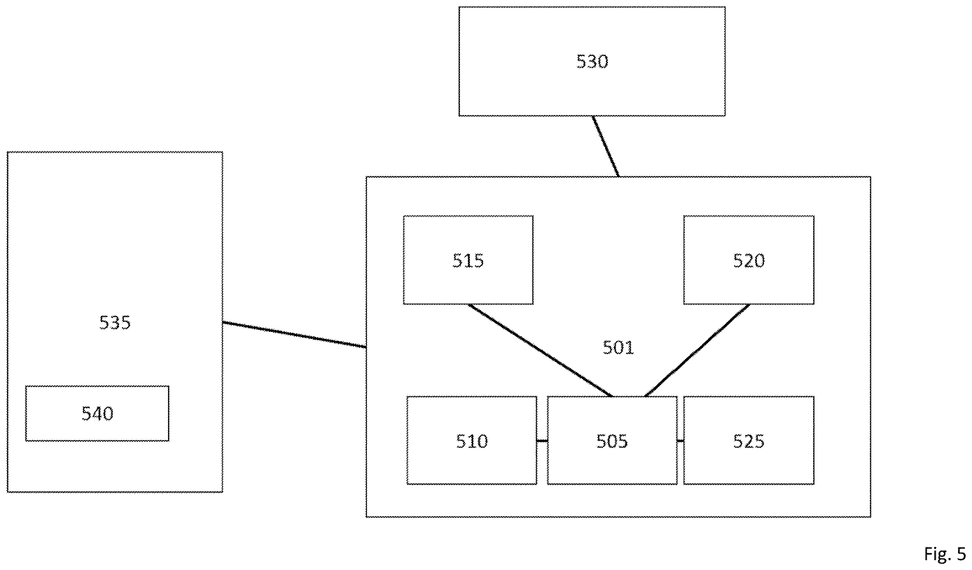

In another illustrative embodiment, the proposed system can be implemented in part using one or more computer systems that are programmed or otherwise configured to implement methods described herein for acquiring PEEM images. FIG. 5 shows a computer system 501 that is programmed or otherwise configured to implement a method for acquiring PEEM images of biomedical samples with accelerated throughput in accordance with an illustrative embodiment. The computer system may be configured to provide autofocus and/or automation of other image optimization functionality. In some embodiments, the computer system may execute a preliminary imaging run to detect optimized imaging parameters at more than 1, 10, 100, or any other number of regions of interest (ROIs), and may interpolate optimized imaging conditions for the whole wafer from those ROIs.

In one embodiment, the computer system 501 can generate a command or signal that triggers a device or mechanism to readout a sensor once the stage setup is in the appropriate position. The computer system 501 can be an electronic device of a user or a computer system that is remotely located with respect to the electronic device. The electronic device can be a mobile electronic device. The computer system 501 may include a central processing unit (CPU, also “processor” and “computer processor” herein) 505, which can be a single core or multi core processor, or a plurality of processors for parallel processing. The computer system 501 also includes memory or memory location 510 (e.g., random-access memory, read-only memory, flash memory), electronic storage unit 515 (e.g., hard disk), communication interface 520 (e.g., network adapter) for communicating with one or more other systems, and peripheral devices 525, such as cache, other memory, data storage and/or electronic display adapters.

The memory 510, storage unit 515, interface 520 and peripheral devices 525 are in communication with the CPU 505 through a communication bus (solid lines), such as a motherboard. The storage unit 515 can be a data storage unit (or data repository) for storing data. The computer system 501 can be operatively coupled to a computer network (“network”) 530 with the aid of the communication interface 520. The network 530 can be the Internet, an internet and/or extranet, or an intranet and/or extranet that is in communication with the Internet. The network 530 in some cases is a telecommunication and/or data network. The network 530 can include one or more computer servers, which can enable distributed computing, such as cloud computing. The network 530, in some cases with the aid of the computer system 501, can implement a peer-to-peer network, which may enable devices coupled to the computer system 501 to behave as a client or a server.

The CPU 505 can execute a sequence of machine readable instructions, which can be embodied in a program or software. The instructions may be stored in a memory location, such as the memory 510. The instructions can be directed to the CPU 505, such that the CPU 505 implements methods of the present disclosure. Examples of operations performed by the CPU 505 can include fetch, decode, execute, and writeback. The CPU 505 can be part of a circuit, such as an integrated circuit. One or more other components of the system 501 can be included in the circuit. In some cases, the circuit is an application specific integrated circuit (ASIC).

The storage unit 515 can store files, such as drivers, libraries and saved programs. The storage unit 515 can store user data, e.g., user preferences and user programs. The computer system 501 in some cases can include one or more additional data storage units that are located external to the computer system 501 (e.g., on a remote server that is in communication with the computer system 501 through an intranet or the Internet). The computer system 501 can communicate with one or more remote computer systems through the network 530. For instance, the computer system 501 can communicate with a remote computer system. Examples of remote computer systems include personal computers (e.g., portable PC), slate or tablet PC's (e.g., Apple® iPad, Samsung Galaxy Tab), telephones, Smart phones (e.g., Apple® iPhone, Android-enabled device, Blackberry®), or personal digital assistants.

The user can access the computer system 501 via the network 530. Methods as described herein can be implemented by way of machine (e.g., computer processor) executable code stored on an electronic storage location of the computer system 501, such as, for example, on the memory 510 or electronic storage unit 515. The machine executable or machine readable code can be provided in the form of software. During use, the code can be executed by the processor 505. In some cases, the code can be retrieved from the storage unit 515 and stored on the memory 510 for ready access by the processor 505. In some situations, the electronic storage unit 515 can be precluded, and machine-executable instructions are stored on memory 510. The code can be pre-compiled and configured for use with a machine having a processor adapted to execute the code, or can be compiled during runtime.

The code can be supplied in a programming language that can be selected to enable the code to execute in a pre-compiled or as-compiled fashion. Various aspects of the systems and methods provided herein, such as the computer system 501, can be embodied in programming. Various aspects of the technology may be thought of as “products” or “articles of manufacture” typically in the form of machine (or processor) executable code and/or associated data that is carried on or embodied in a type of machine readable medium. Machine-executable code can be stored on an electronic storage unit, such as memory (e.g., read-only memory, random-access memory, flash memory) or a hard disk. “Storage” type media can include any or all of the tangible memory of the computers, processors or the like, or associated modules thereof, such as various semiconductor memories, tape drives, disk drives and the like, which may provide non-transitory storage at any time for the software programming.

All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution. Hence, a machine readable medium, such as computer-executable code, may take many forms, including but not limited to, a tangible storage medium, a carrier wave medium or physical transmission medium.

Non-volatile storage media including, for example, optical or magnetic disks, or any storage devices in any computer(s) or the like, may be used to implement the databases, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CDROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

The computer system 501 can include or be in communication with an electronic display 535 that comprises a user interface (UI) 540. The portal may be provided through an application programming interface (API). A user or entity can also interact with various elements in the portal via the UI. Examples of UI's include, without limitation, a graphical user interface (GUI) and web-based user interface.

Imaging by the proposed system was tested by the inventors on a biological sample in the form of a mouse brain slice. The mouse brain sample was stained using standard staining protocols for biological electron microscopy and embedded in epoxy resin. The polymer block was then ultramicrotomed to 40-80 nm thin sections on an air table to avoid chatters. A silicon substrate (7×7 mm²) coated with ~50 nm polycrystalline gold (poly-Au) was used for picking up as-cut sample sections from a water tank. The gold layer is used for several purposes including enhancing the conductivity of the substrate and providing a better adhesion of the biological sample to the substrate as gold has the tendency to bond to sulfur. The gold layer also enables the user to quickly locate bio-sections based on the distinct photoemission intensities from gold and the sample sections. This practice proves to bring major improvements to image resolution and significantly reduces arcing effects that are likely due to the poor contact of sample sections with a native oxide layer on bare silicon.

In the proposed system, a careful selection of light source is critical to obtaining a sharp subcellular resolution image. First, photon energy needs to surpass the work function of bio-sections such that photoelectrons can emit and be detected to form images. Second, photon flux needs to not only be sufficiently high to increase S/N per unit time and thus speed up data acquisition, but also to be kept below the space charging limit. In addition, using power that is too high can be detrimental to samples due to thermal heating.

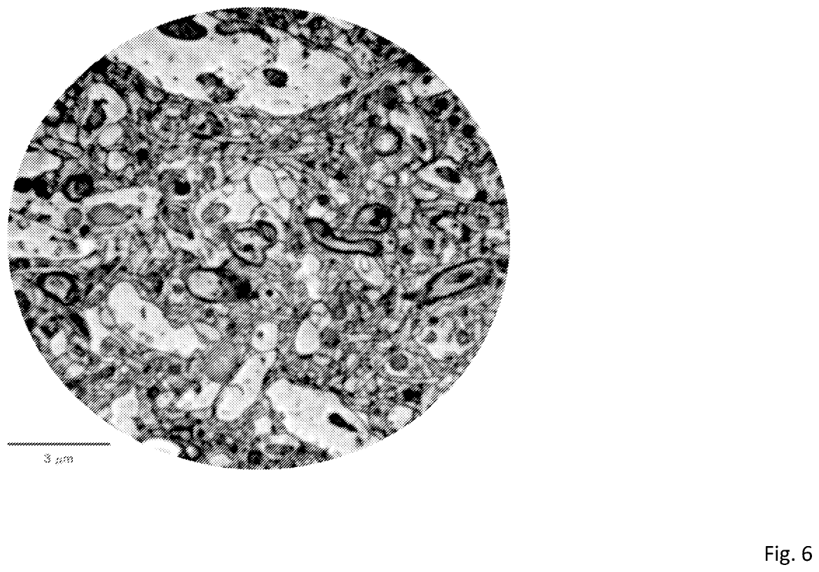

The inventors verified the feasibility of the bio-PEEM using a continuous-wave (CW) mercury (Hg) lamp at room temperature. The Hg lamp used for testing has a broadband spectrum where the shortest wavelength is around 250 nm (4.96 eV), and luminance of the UV part is ≤566 cd/mm². The initial operation of imaging involves driving the sample stage and finding the sections on the surface. Poly-Au has a lower work function and higher density of states (DoS) than biological samples and epoxy resins. At this photon energy, it exhibits much stronger photoemission than the sample sections. Therefore, sample sections can be easily identified at 100s μm field of view (FoV) by looking for notably darker rectangular areas with sharp edges. Unlike conventional imaging of homogenous material systems, cellular structures are hardly observable until high magnification is reached by incrementally increasing extractor voltage up to 12 kV. This requires continuously zooming in at regions of interest (RoIs) down to <20 μm FoV. A smaller aperture (150 μm) is usually used to further improve image resolution. Both conditions restrict the total amount of photoelectrons arriving at the detector, thus the image intensity is normally very low without seconds of camera exposure time. This makes it extremely challenging to perform focus and stigmator optimization in the live mode. FIG. 6 is a representative image of an 80-nm thick sample section illuminated by a mercury lamp in accordance with an illustrative embodiment. The spatial resolution is 40-50 nm, which is found by calculating the width between 16% and 84% of the error function.

Thus, described herein are various embodiments of photoemission electron microscopes (PEEM) that are used to image samples of a biological material origin and/or are optimized for fast imaging, surpassing the state of the art in terms of speed by several magnitudes by a series of measures detailed here. In one embodiment, one or several of the components of a PEEM are optimized for the task at hand, such as faster detectors, brighter illuminations, movement apparatuses for reduced overhead, and optimized sample preparation and presentation. In some embodiments this setup may be optimized for the rapid acquisition of 3D image stacks of biological tissue such a brain matter or cancer tissue, allowing much greater volumes to be imaged at high resolution.

In an illustrative embodiment, any of the operations described herein can be performed by a computing system that includes a processor, a memory, a user interface, a transceiver, etc. The memory can be used to store computer-readable instructions that, upon execution by the processor, cause the computing system to perform the operations described herein. All or a portion of the computing system can be incorporated into a robot unit. For example, the computing system can be incorporated onto the printed circuit board of an individual robotic unit. All or a portion of the computing system can also be in the form of a system that is remote from the robotic units and used to monitor and/or control them.

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

Whenever the term “at least,” “greater than,” or “greater than or equal to” precedes the first numerical value in a series of two or more numerical values, the term “at least,” “greater than” or “greater than or equal to” applies to each of the numerical values in that series of numerical values. For example, greater than or equal to 1, 2, or 3 is equivalent to greater than or equal to 1, greater than or equal to 2, or greater than or equal to 3. Whenever the term “no more than,” “less than,” or “less than or equal to” precedes the first numerical value in a series of two or more numerical values, the term “no more than,” “less than,” or “less than or equal to” applies to each of the numerical values in that series of numerical values. For example, less than or equal to 3, 2, or 1 is equivalent to less than or equal to 3, less than or equal to 2, or less than or equal to 1.

The term “real time” or “real-time,” as used interchangeably herein, generally refers to an event (e.g., an operation, a process, a method, a technique, a computation, a calculation, an analysis, a visualization, an optimization, etc.) that is performed using recently obtained (e.g., collected or received) data. In some cases, a real time event may be performed almost immediately after an initial event or within a short enough time span after such initial event, such as within at most 1 second, 0.5 seconds, 0.1 seconds, 0.05 seconds, 0.01 seconds, 5 ms, 1 ms, 0.5 ms, 0.1 ms, 0.05 ms, 0.01 ms, 0.005 ms, 0.001 ms, 0.0005 ms, 0.0001 ms, or less.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more.”

The foregoing description of illustrative embodiments of the invention has been presented for purposes of illustration and of description. It is not intended to be exhaustive or to limit the invention to the precise form disclosed, and modifications and variations are possible in light of the above teachings or may be acquired from practice of the invention. The embodiments were chosen and described in order to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

1. An imaging system comprising:
a light source configured to radiate a biological sample, wherein the light source is optimized for rapid imaging of the biological sample using a photoelectric effect;
a sample holder configured to secure the biological sample during imaging;
a stage assembly to which the sample holder is mounted, wherein stage assembly moves the biological sample during imaging; and
a detector configured to receive electrons emitted from the biological sample in response to radiation from the light source.

2. (canceled)

3. (canceled)

4. (canceled)

5. (canceled)

6. The system of claim 1, further comprising a reflective coating on the sample holder to mitigate negative effects of heat deposition during imaging.

7. The system of claim 1, wherein the light source comprises a frequency-quadrupled neodymium-doped yttrium aluminum garnet (Nd:YAG) laser.

8. The system of claim 1, further comprising one or more mirrors that direct light from the light source onto the biological sample.

9. (canceled)

10. The system of claim 1, further comprising a fiber cable connected to the light source, wherein the fiber cable is also connected to a vacuum chamber where imaging takes place.

11. The system of claim 1, further comprising an objective lens configured to focus radiation from the light source onto a region of interest (ROI) of the biological sample.

12. The system of claim 1, wherein the stage assembly includes a plurality of stages combined in aggregate to provide both speed and a lack of vibration over a range of travel that exceeds a size of the biological sample.

13. The system of claim 12, wherein a first stage in the plurality of stages is a piezo driven flexure stage or magnetic bearing stage and a second stage in the plurality of stages is a cross roller bearing stage.

14. The system of claim 1, further comprising one or more sensors to monitor a Z stage of the stage assembly that moves in a Z-direction, wherein the one or more sensors identify any movement errors in the Z-direction.

15. The system of claim 1, further comprising a vacuum aperture positioned between the biological sample and the stage assembly such that the stages of the stage assembly and the biological sample can be separately pumped.

16. The system of claim 1, wherein the detector is configured for continuous imaging while the sample is moving.

17. The system of claim 16, further comprising an electric or electromagnetic deflector in a path of the electrons emitted from the biological sample to deflect the electrons using a sawtooth deflection amplitude.

18. The system of claim 1, wherein the sample holder includes a wafer submerged in water, wherein the biological sample is received on the water, and wherein the water is removed via draining or evaporation such that the biological sample is positioned on the wafer.

19. The system of claim 18, wherein the biological sample is fused with a block of magnetic material such that a position of the biological sample received on the water can be manipulated by a magnet.

20. The system of claim 1, further comprising a staining agent introduced into the biological sample to highlight one or more regions of the biological sample, wherein the staining agent has a modified electron yield during photoemission conditions.

21. The system of claim 1, wherein the biological sample is stained with Osmium tetroxide and embedded in epoxy, and wherein the biological sample stained with Osmium tetroxide has an increased electron yield compared to the epoxy.

22. (canceled)

23. The system of claim 1, wherein the sample holder is treated with ionic radiation to remove a portion of the sample one or more times during imaging.

24. (canceled)

25. The system of claim 1, further comprising a treatment applied to the sample holder to minimize light absorption, wherein the treatment makes the sample holder transparent to light having a wavelength used to elicit the electrons.

26. The system of claim 1, wherein a surface of the sample holder is modified into a Bragg mirror to make the sample holder reflective and thereby minimize light absorption.

27. The system of claim 1, wherein the light source has a wavelength in a range between 157 nanometers and 300 nanometers.
